(19) United States
(12) Patent Application Publication
(10) Pub. No.: US 2022/0255001 A1
(43) Pub. Date: Aug. 11, 2022

(54) SELECTED-AREA DEPOSITION OF HIGHLY ALIGNED CARBON NANOTUBE FILMS USING CHEMICALLY AND TOPOGRAPHICALLY PATTERNED SUBSTRATES

(71) Applicant: Wisconsin Alumni Research Foundation, Madison, WI (US)

(72) Inventors: Padma Gopalan, Madison, WI (US); Jonathan H. Dwyer, Madison, WI (US); Katherine Jinkins, Evanston, IL (US); Michael Scott Arnold, Middleton, WI (US)

(21) Appl. No.: 17/591,711

(22) Filed: Feb. 3, 2022

Related U.S. Application Data
(60) Provisional application No. 63/147,043, filed on Feb. 8, 2021.

(51) Int. Cl. H01L 51/00

(52) U.S. Cl. CPC H01L 51/0003; H01L 51/0558; H01L 51/0048

(57) ABSTRACT

Methods for forming films of aligned carbon nanotubes are provided. Also provided are the films formed by the methods and electronic devices that incorporate the films as active layers. The films are formed by flowing a suspension of carbon nanotubes over a substrate surface that is chemically and topographically patterned. The methods provide a rapid and scalable means of forming films of densely packed and aligned carbon nanotubes over large surface areas.

### CROSS-REFERENCE TO RELATED APPLICATIONS

The present application claims priority to U.S. provisional patent application No. 63/147,043 that was filed Feb. 8, 2021, the entire contents of which are incorporated herein by reference.

### REFERENCE TO GOVERNMENT RIGHTS

This invention was made with government support under 1727523 awarded by the National Science Foundation. The government has certain rights in the invention.

### BACKGROUND

Semiconducting single-walled carbon nanotubes (s-CNTs) are excellent candidates for next-generation field-effect transistors (FETs) due to their outstanding properties such as ballistic transport, excellent charge mobility, and high thermal conductivity. However, to date, the vast majority of s-CNT-based FETs have underperformed compared with conventional Si- and GaAs-based FETs due to two main factors. One of these factors is the need to achieve greater than 99.99% semiconducting CNTs from an electronically heterogenous CNT mixture. This material processing challenge has been largely overcome through a number of sorting agents in both aqueous and organic solvents. The second issue relates to the difficulty of scaling single s-CNT devices to s-CNT array devices. An ideal s-CNT array requires deposition to be spatially controlled with a small pitch and a high density, while tightly aligning s-CNTs, preventing their overlap and achieving parallel alignment with each other.

Two primary pathways are typically utilized to obtain aligned s-CNT arrays: (1) direct growth of s-CNT arrays through chemical vapor deposition (CVD); and (2) s-CNT deposition from solution. CVD growth uses CNT growth precursors on catalytic substrates to fabricate aligned s-CNT arrays. Advantages to CVD methods include high degrees of s-CNT alignment in arrays, as well as the relative ease of patterning catalytic materials for localized s-CNT growth. High densities have been achieved. However, the major disadvantage of the CVD growth method is the concurrent growth of both s-CNTs and metallic CNTs (m-CNTs), hence lowering current on/off ratios. Although progress has been made in selectively synthesizing s-CNTs using CVD and removing m-CNTs post-synthetically, the purity levels do not approach those required for high-performing s-CNT-based devices. In addition, most CVD CNT growth mechanisms require specific substrates such as sapphire and quartz. Thus, an additional CNT array transfer step is needed to deposit CVD grown s-CNTs on traditional metal oxide semiconductor field-effect transistor (MOSFET) substrates like Si wafers.

In contrast to CVD growth mechanisms, high s-CNT purities are attainable by dispersing s-CNTs in solution to create “inks”. To overcome inter-CNT π-π interactions to individualize and de-aggregate s-CNTs, dispersing agents are typically necessary. Dispersants such as aromatic conjugated polymers which interact non-covalently with CNTs are also able to sort CNT soot into high-purity, electronics-grade s-CNT inks. From these inks, alignment of s-CNTs on substrates has been achieved through various methods including Langmuir-Blodgett/Schaefer, vacuum filtration, electric fields, shear, evaporation, three-dimensional (3D) printing, and at liquid/liquid interfaces. While these studies have made progress in fabricating continuously aligned s-CNTs on wafer-scale, selective area deposition as well as controlling their pitch in a scalable manner are still unresolved.

Current selective area CNT deposition methods include covalent bonding with the substrate, tailored electrostatic interactions between a polymer wrapper and a substrate, and use of DNA-based nanotrench guides. However, simultaneously achieving high density of perfectly aligned CNTs in selective regions of the substrate on a wafer scale without compromising on electronic properties is an outstanding challenge.

### BRIEF DESCRIPTION OF THE DRAWINGS

Illustrative embodiments of the invention will hereafter be described with reference to the accompanying drawings, wherein like numerals denote like elements.

FIGS. 1A-1C show schematics for s-CNT array fabrication using (FIG. 1A) chemical patterns where the methyl groups represent an octadecyltrichlorosilane (OTS)-grafted self-assembled monolayer (SAM), (FIG. 1B) topographical patterns with SAM functionalization on both a mesa and a trench sidewall where the methyl groups represent an 1-octadecanethiol (OTh)-grafted SAM, and (FIG. 1C) topographical patterns with functionalization of mesas with OTh-grafted SAM. White line labelled ‘w’ represents (FIG. 1A) SiO₂ stripe width and (FIG. 1B, 1C) trench width.

FIG. 2A shows scanning electron microscopy (SEM) images of poly[(9,9-dioctylfluorenyl-2,7-diyl)-alt-co-(6,6′-[2,2′-{bipyridine])] (PFO-BPy) wrapped s-CNTs shear deposited across alternating OTS (bright) and SiO₂ (dark) stripes. From left to right, SiO₂ stripes are 1000, 500, and 250 nm wide. Scale bar is 1 micron, for all images. High resolution SEM images of 500 nm (FIG. 2B) and 250 nm (FIG. 2C) show the s-CNTs pinned from SiO₂ stripes across to the OTS stripes. Cartoon (right) depict the location of these pinned s-CNTs.

FIG. 3A shows a SEM image of s-CNT arrays in 250 nm wide trenches where s-CNTs were deposited at a shear rate of 4,600 s⁻¹ in 25 nm tall OTh-grafted Au/Cr trenches. FIG. 3B shows a plot of CNT alignment degree as characterized by the standard deviation (a) from the two-dimensional fast Fourier transform (2D FFT) analysis as a function of both trench width and shear rate. FIG. 3C shows a side-by side comparison of representative SEM images at a constant deposition shear rate of 4,600 s⁻¹ for bulk, 250 nm and 100 nm wide trenches demonstrating s-CNT alignment improvement as trench width decreases. Images for 250 and 100 nm wide trenches contain multiple individual trenches adjacent to each other stitched together (ticks show stitch locations). Scale bar is 250 nm and same for all images.

FIGS. 4A-4B show SEM images of polymer-wrapped s-CNTs sheared at 4,600 s⁻¹ across 250 nm OTh-SiO₂ wide trench arrays (FIG. 4A) before and (FIG. 4B) after Cu/Au trench removal. FIG. 4C shows a process schematic for trench removal. FIG. 4D shows a plot showing averaged Raman spectra over a 34 μm² area of CNTs before and after trench removal normalized to the Si peak. “After” spectrum is offset by 0.01 to improve readability.

FIGS. 5A-5C show 2D FFT methodology used to quantify s-CNT alignment in arrays. FIG. 5A shows a SEM image of 500 nm wide s-CNT arrays (dark stripes) spaced 500 nm apart from surface pattern (bright stripes). FIG. 5B shows a SEM image of s-CNT arrays from the image shown in FIG. 5A stitched together. FIG. 5C shows orientation distribution from 2D FFT (points) obtained by integrating the FFT intensity radially from fₘᵢₙ to fₘₐₓ, for all angles between −90 to 90 degrees. Line is Gaussian curve fit of data, which outputs a standard deviation (a) used as the s-CNT alignment degree.

FIG. 6 shows SEM images of CNTs deposited on a OTh-grafted gold surface compared to on SiO₂. CNTs were deposited using 375 μL of 240 μg/mL solution in chloroform at a shear rate of 46,000 s⁻¹.

FIGS. 7A-7B show SEM images showing the CNT arrays on stripes in between a 40 nm tall OTh functionalized Au/Cr stack when the stack composition is (FIG. 7A) 2.5 nm Cr and 37.5 nm Au on top, and (FIG. 7B) 37.5 nm Cr and 2.5 nm Au on top. FIG. 7C shows a SEM image of CNT deposition on bulk SiO₂ away from patterns.

FIGS. 8A-8B show plots of CNT density (CNTs μm⁻¹) versus: (FIG. 8A) trench width w at constant 4,600 s⁻¹ shear rate, and (FIG. 8B) shear rate at constant w of 250 nm. Insets in both plots are representative SEM images of corresponding data points. CNT density was obtained by counting the CNTs along the CNT diameter axis to generate the reported linear density. Five measurements were made over three samples to generate each data point and error bars on the plots.

FIGS. 9A-9B show SEM images of s-CNT deposition at 46 s⁻¹ shear rate using 375 μL s-CNT chloroform ink at a concentration of 240 μg/mL. Images are on (FIG. 9A) planar SiO₂ (bulk) and (FIG. 9B) in 100 nm trench. FIG. 9B is multiple 100 nm trenches stitched together used for 2D FFT analysis. Scale bar is 500 nm for both images.

FIG. 10A shows a plot showing the s-CNT alignment degree before and after trench removal. FIGS. 10B-10C show stitched together s-CNT arrays from a SEM image of 250 nm wide trenches (FIG. 10B) before and (FIG. 10C) after removal.

FIGS. 11A-11B show SEM images showing a 1-μm wide s-CNT array (FIG. 11A) before and (FIG. 11B) after the crossing CNTs deposited on OTh-grafted gold surface are removed via reactive-ion etching procedure. Scale bar of 1 μm is the same for both images.

### DETAILED DESCRIPTION

Methods for forming films of aligned carbon nanotubes are provided. Also provided are the films formed by the methods and electronic devices that incorporate the films as active layers. The films are formed by flowing a suspension of carbon nanotubes over a substrate surface that is chemically and topographically patterned. The methods provide a rapid and scalable means of forming films of densely packed and aligned carbon nanotubes over large surface areas.

By patterning a substrate surface with chemical functionalities and topographical features and, optionally, pre-aligning CNTs via shear force in a liquid flow, selective-area deposition of films of aligned CNT can be formed with controlled locations. The CNTs used to form the films may be single-walled CNTs, including single-walled CNTs processed from high pressure carbon monoxide (HiPco) produced powders and single-walled CNTs made via arc-discharge methods. The CNTs are characterized by very small diameters; for example, less than 5 nm and more typically less than 2 nm. CNTs of various lengths can be aligned using the methods. This includes very short CNTs that have lengths of no greater than 1 μm, including CNTs having lengths of no greater than 750 nm, or no greater than 500 nm. By way of illustration, the CNTs may have diameters in the range from 1 nm to 2 nm and/or lengths in the range from 100 nm to 600 nm. This is significant because short nanotubes are substantially more difficult to align than their longer counterparts. In a sample (e.g., powder) of CNTs in which the dimensions of the individual CNTs vary, the dimensions recited above refer to the average dimensions for the CNTs in the sample. However, the samples can be selected such that all, or substantially all (e.g., >98%), of the CNTs fall within the recited length and diameter ranges.

For some device applications, it is desirable for the CNTs to be semiconducting single-walled CNTs (s-CNTs). Therefore, the carbon nanotubes used in the methods can be pre-sorted to remove all, or substantially all (e.g., >90%), of the metallic CNTs (m-CNTs). However, the alignment of metallic CNTs can also be aligned using the methods disclosed herein.

The individual CNTs can be coated with an organic material in order to facilitate their alignment and deposition onto a deposition substrate and/or to avoid aggregation in the suspension or in the films made therefrom. For clarification, these coated CNTs each have a partial or complete film of an organic material on their surface; they are not all dispersed in a continuous organic (e.g., polymer) matrix. The coatings may be, but need not be, covalently bonded to the surfaces of the CNTs. Organic materials that can form the coatings include monomers, oligomers, polymers, and combinations thereof. The coating may be a coating that was used in a pre-sorting step to isolate s-CNTs from a mixture of s-CNTs and m-CNTs. These types of coatings, which are referred to herein as semiconductor-selective coatings, include polythiophenes and polycarbazoles, among others. A number of semiconductor-selective coatings are known, including semiconductor-selective polymer coatings. Descriptions of such polymers can be found, for example, in Nish et al., Nat. Nanotechnol. 2007, 2, 640-6 and in Brady et al., Science Advances, 2016, 2, e1601240. The semiconductor-selective polymers are typically organic polymers with a high degree of π-conjugation and include polyfluorene derivatives and poly(phenyl vinylene) derivatives. Polyfluorene derivatives include copolymers containing dialkyl-fluorene and bipyridine units. These include poly(9,9-dialkyl-fluorene) copolymers having bipyridine units (e.g., poly[(9,9-dioctylfluorenyl-2,7-diyl)-alt-co-(6,6′-[2,2′-{bipyridine]). While the semiconductor-selective coatings may be conductive or semiconductive materials, they can also be electrically insulating. Optionally, the coatings can be removed from the CNTs after the CNT films have been deposited. For example, the coatings can be selectively dissolved or etched away. Alternatively, for polymers having a bipyridine repeat unit, the coatings can be removed via exposure to a transition metal salt, such as a transition metal (e.g., rhenium) carbonyl salt, as described in U.S. Pat. No. 9,327,979.

The CNTs are dispersed in a liquid to provide a suspension of the CNTs. A wide variety of organic solvents and mixtures of organic solvents can be used to form the suspension. The organic solvent desirably has a relatively high boiling point at the film deposition temperature and pressure, typically ambient temperature and pressure, such that it evaporates slowly. Examples of solvents having relatively high boiling points include toluene and 1,2-dichlorobenzene. However, lower boiling organic solvents, such as chloroform, can also be used. The concentration of the CNTs in the fluid suspension may affect the density of the CNTs in the deposited films. A wide range of CNT concentrations can be employed. By way of illustration only, in some embodiments of the methods, the suspension has a CNT concentration in the range from 0.01 μg/mL to 1000 μg/mL, including concentrations in the range from 20 μg/mL to 500 μg/mL.

The substrate over which the suspension flows and onto which the CNT films are deposited, referred to as a deposition substrate, can be topographically patterned by forming one or more trenches over the substrate. The trenches are defined by two opposing sidewalls spaced apart by a gap and a trench floor spanning the gap between the sidewalls, where the trench floor is the deposition substrate upon which the CNT films are deposited.

The trenches may be formed by raised structures, referred to as mesas, on the surface of a deposition substrate. It should be understood that, as used herein, the term “mesas” is not limited to raised structures that are patterned into the surface of a substrate, but refers more generally to a structure that stands up above the surface of the deposition substrate to form a trench sidewall. Thus, mesas may be made by depositing material onto the surface of a deposition substrate. The mesas are separated from one another by a gap, such that portions of the deposition substrate surface are exposed in the gaps between the mesas. The sides of the mesas provide the sidewalls of the trenches and, therefore, the mesas are referred to as sidewall mesas. The materials used for the surface of the deposition substrate and the trench sidewalls are selected such that CNTs in the flowing suspension preferentially adhere to the deposition substrate, as opposed to the trench sidewalls. The mesas may be straight, have uniform dimensions along their lengths, and may be aligned in a parallel arrangement to provide a plurality of uniform parallel stripes of exposed deposition substrate. However, the mesas need not be straight, have uniform dimensions along their lengths, and/or be aligned in parallel; the mesas may be designed to form a CNT film in a pattern other than a striped line pattern.

The gap between the trench sidewalls defines the width of the trench and determines the width of the deposited CNT films. In some embodiments of the methods for depositing films of aligned CNTs, the one or more trenches have widths in the range from 50 nm to 5000 nm. This includes embodiments in which the one or more trenches have widths in the range from 10 nm to 2000 nm. This also includes trenches having widths of less than 500 nm, such as trenches having widths in the range from 25 nm up to 500 nm and in the range from 50 nm to 250 nm. In order to maximize the degree of alignment of the CNTs in the deposited films, the trenches may have widths that are smaller than the lengths of the CNTs in the suspensions. In some embodiments, the trench width is less than half the average length of the CNTs in the suspension. This includes embodiments in which the trench width is less than a quarter of the average length of the CNTs in the suspension. When the trench widths are reduced to less than the width of the CNTs, confinement effects become dominant, enabling the selective-area deposition of more tightly aligned CNTs. However, trenches having widths greater than the average length of the CNTs in the suspension can be used. The height of the trench sidewalls should be sufficient to prevent CNTs from depositing on more than one exposed region of the deposition substrate. Generally, a trench height that is at least ten times the diameter of the CNTs is sufficient. For example, trench heights of 25 nm or greater can be used. After the films of aligned CNTs have been formed on the deposition substrate, the mesas can be removed, along with any CNTs that have adsorbed onto the mesa surfaces.

In addition to the topographical patterning provided by the trenches, chemical patterning is used to enhance the deposition of the CNT films on the trench floor. This is accomplished by functionalizing the tops and/or sides of the mesas with organic chemical groups that render the deposition of CNTs on functionalized regions of the mesas unfavorable, relative to regions of the mesas that are not functionalized with the chemical groups. As used herein, the term “functionalizing” refers to chemically bonding (e.g., grafting) a chemical group to the surface of a substrate. Thus, the chemical groups functionalizing a surface differ from chemical groups that make up the surface of a substrate and that are an inherent part of the substrate material.

In the absence of topographical features, the chemical groups can be patterned on the deposition substrate as a series of parallel stripes, with alternating stripes of deposition substrate exposed between the chemically patterned stripes. When a suspension of CNTs flows over the chemically patterned substrate along the stripe direction (i.e., when the suspension flows parallel with the stripes), the CNTs preferentially adhere to the exposed regions of the deposition substrate.

The gap between the chemically patterned strips determines the width of the deposited CNT films. In some embodiments of the methods for depositing films of aligned CNTs, the gaps have widths in the range from 50 nm to 5000 nm. This includes embodiments in which the gaps have widths in the range from 100 nm to 2000 nm. This also includes gaps having widths of less than 500 nm, such as gaps having widths in the range from 100 nm up to 500 nm and in the range from 100 nm to 250 nm.

A combination of topographical and chemical patterning can be achieved by forming one or more mesas on the surface of a deposition substrate and patterning the top surfaces and/or the sides of the mesas with chemical groups that render the deposition of CNTs on the top surfaces and/or sides of the mesas unfavorable, relative to the deposition of the CNTs on the trench floors. Notably, while it is possible to functionalize the entire trench sidewall—from where the sidewall meets the trench floor up to the top of the mesa—a CNT film having a higher density of CNTs can be formed on the trench floor if the portion of the trench sidewall adjacent to the trench floor remains unfunctionalized. For example, limiting the chemical functionalization to the top surfaces of the mesas and/or the uppermost portions of the mesa sides can increase the density of CNTs in the deposited films by at least a factor of five (e.g., a factor of 5-10, or more), relative to mesas having sides that are fully functionalized. Without intending to be bound to any particular theories of the inventions, this effect may be attributed to the avoidance of the disruption of the solvent structure along the trench sidewalls as the CNT suspension passes through the trench. Thus, in some embodiments of the topographically and chemically patterned trenches, only the top surfaces, the top ends of the sidewalls, or both are functionalized with the chemical groups.

The CNT film-forming methods are carried out by creating a flow of a suspension comprising the CNTs over through a trench. As the suspension of CNTs flows through the trench, the CNTs become aligned with their long axes (lengths) along the direction of the flow. Alignment may be due to, for example, a flow velocity gradient (shear rate) that gives rise to shear forces that align the CNTs. Thus, when the carbon nanotubes in the flowing suspension contact the deposition substrate, they are deposited on the surface of the deposition substrate with their long axes oriented in the direction of the flow. Alignment of the CNTs can be achieved using a broad range of shear rates, including shear rates in the range from 40 s⁻¹ to 50,000 s⁻¹. The deposition of the CNTs can take place while the suspension is flowing and does not require the use of a charged deposition substrate, electrodes, or evaporation from a stationary (non-flowing) suspension.

As discussed above, the deposition substrate is composed of a material to which the CNTs, including organic-material coated CNTs, readily adhere. Different deposition substrate materials may be preferred for different CNT coating materials. In some embodiments of the methods, hydrophilic substrates, such as silicon oxide (e.g., SiO₂) can be used. In other embodiments, non-hydrophilic substrates or hydrophobic substrates can also be used. Other deposition substrate materials that can be used include metal oxides (including, but not limited to, aluminum oxide, hafnium oxide, and lanthanum oxide), high-k dielectric materials, such as SiN, and common semiconductor materials, such as silicon and germanium. The deposition substrate can also be a polymer substrate for flexible electronics applications, including but not limited to, polydimethylsiloxane, polyethersulfone, poly(ethylene terephthalate), and the like. The materials listed here may be the materials from which the deposition substrate is entirely composed, or may be applied as coatings over an underlying bulk substrate base. For the purposes of this disclosure, a surface is considered hydrophobic if its static water contact angle θ is >90° and is considered hydrophilic if its static water contact angle θ is <90°.

The material of the mesas that define the sidewalls of the trench and the chemical groups used to functionalize the mesas should be selected such that the CNTs adhere less readily to the sidewalls than to the deposition substrate during the CNT deposition process. And, the mesas should be made from a material that can be selectively functionalized with chemical groups that reduce CNT adsorption, without chemically modifying the deposition substrate. Thus, for CNTs that are coated with an organic material, different mesa materials and chemical functionalities may be preferred for different CNT coating materials. By way of illustration only, for organic material-coated CNTs that adhere well to a hydrophobic deposition substrate, the trench sidewalls may be composed of a material that is less hydrophobic than the material from which the deposition substrate is composed. Similarly, for organic material-coated CNTs that adhere well to a hydrophilic deposition substrate, the trench sidewalls may be composed of a material that is less hydrophilic than the material from which the deposition substrate is composed. Examples of suitable materials for the mesas include, but are not limited to, metals, fluoropolymers, such as polytetrafluoroethylene and Viton, and glass or quartz coated with a hydrophobic polymer. Uncoated glass and quartz can also be used. The use of metals as mesa materials is advantageous because metals can be deposited as thin layers using straight-forward methods, such as evaporation, can be functionalized with a variety of chemical groups, and can be selectively removed after the CNT films have been deposited.

Alkyl groups, such as C₁-C₂₀ alkyl chains, are examples of hydrophobic chemical groups that can be attached to at least some portions of the mesas in order to reduce unwanted adhesion of CNTs coated with a hydrophilic coating. The mesas can be functionalized using, for example, organic molecules that form a SAM on the top and/or sides of the mesas. Such organic molecules are characterized by a hydrophobic tail group (e.g., an alkyl tail group) that renders the functionalized surface hydrophilic head groups, such as a thiol group, that attaches the molecule to the deposition substrate.

Gold is an example of a material that can be selectively functionalized with a SAM under conditions in which a hydrophilic surface, such as a silicon dioxide surface, would remain unfunctionalized. SAM-forming organic molecules having a thiol head group and as alkyl tail functionalized include thiols having octyl, dodecyl, and higher (e.g., octadecyl) alkyl groups. As noted above, it may be advantageous to functionalize the top surfaces of the mesas, but not the sides. Thus, in some embodiments of the topographically and chemically patterned substrates, the mesas comprise a top layer formed from a first material that is readily functionalized with chemical groups that render the deposition of CNTs unfavorable and an underlying layer of a different material that is not functionalized with the chemical groups. The lower layer may also act as an adhesion layer that adheres the top layer to deposition substrate. By way of illustration, the mesa can comprise a lower chromium or copper layer that defines the sidewalls of the trench and a film of gold on top of the chromium or copper layer that defines the top surface of the mesa. It is not necessary to entirely eliminate the deposition of CNTs on the top and sides of the mesas because any CNTs adhered to the mesas will be removed when the mesas are removed from the deposition surface. The relative thicknesses of the first and second materials that make up the mesa can vary over a wide range. By way of illustration only, in some embodiments of the mesas, the top layer makes up 50% or less of the height of the mesa. This includes embodiments in which the top layer makes up 20% or less, 10% or less, 5% or less, or 1% or less of the height of the mesa.

The present methods do not require that all of the deposited CNTs be aligned; only that the average degree of alignment of the CNTs in the film is measurably greater than that of an array of randomly oriented CNTs. The degree of alignment in the CNTs in the films refers to their degree of alignment along their longitudinal axes within the films, which can be quantified using two-dimensional fast Fourier transform (2D-FFT), as described in the Example. The methods described herein are able to produce films in which the CNTs have a degree of alignment, as measured by 2D-FFT, of 18° or better. This includes films in which the CNTs have a degree of alignment of 15° or better, and further includes films in which the CNTs have a degree of alignment of 10° or better. By way of illustration only, some embodiments of the films have a CNT degree of alignment in the range from 5° to 10° (e.g., 6° to 9°).

The density of CNTs in the arrays refers to their linear packing density, which can be quantified in terms of the number of carbon nanotubes per μm and measured using scanning electron microscopy (SEM) image analysis, as described in the Example. The methods described herein are able to produce films in which the CNTs have a density of at least 10 CNTs/μm. This includes films in which the CNTs have a density of at least 20 CNTs/μm and at least 30 CNTs/μm. By way of illustration only, some embodiments of the films have a CNT density in the range from 30 CNTs/μm to 40 CNTs/μm.

The films can be deposited as highly uniform stripes over large surface areas, where a uniform film is a continuous film in which the carbon nanotubes are aligned along a substantially straight path, without domains of randomly oriented carbon nanotubes. To form films over larger areas, multiple narrower films can be placed together in a side-by-side arrangement. Thus, the area over which the CNT films can be formed is not particularly limited and can be sufficiently large to cover an entire semiconductor wafer. By way of illustration, CNT films can be formed over surface areas of at least 1 mm², at least 10 mm², or at least 100 mm², or at least 1 m².

Depending on the intended application of the CNTs, it may be desirable to further pattern the films after their initial deposition. The nature of the pattern in which the film is initially deposited and/or that is formed in the film after it is deposited will depend on the intended application of the film. For example, if an array of aligned s-CNTs is to be used as the channel material in a field effect transistor (FET), a pattern comprising a series of parallel stripes may be used. FETs comprising the films of aligned s-CNTs as channel materials generally comprise a source electrode in electrical contact with the channel material and a drain electrode in electrical contact with the channel material; a gate electrode separated from the channel by a gate dielectric; and, optionally, an underlying support substrate. Various materials can be used for the components of the FET. For example, a FET may include a channel comprising a film comprising aligned s-CNTs, a SiO₂ gate dielectric, a doped Si layer as a gate electrode and metal (Pd) films as source and drain electrodes. However, other materials may be selected for each of these components.

Optionally, if the CNTs are coated with an organic material, the organic material may be removed after the films are formed.

### Example

This example illustrates the use of chemical and topographical patterns to guide selective shear deposition of aligned arrays of s-CNTs from organic solvents. High shear rate deposition on the chemical and topographically contrasted patterns lead to the selective-area deposition of arrays of quasi-aligned CNTs (14 degrees) even in patterns that are wider than the length of the individual nanotubes (>500 nm). However, as the width of the patterns is reduced below the length of the individual nanotubes, confinement effects dominate in the deposition process, leading to selective-area deposition of more tightly aligned CNTs (7 degrees). These arrays were characterized for s-CNT density via SEM image analysis and CNT alignment degree via a 2D FFT methodology. It was also demonstrated that these surface patterns can be removed after CNT deposition resulting in aligned, spatially selective s-CNT arrays for devices.

### Experimental

### Poly[(9,9-dioctylfluorenyl-2,7-diyl)-alt-co-(6,6′-[2,2′-bipyridine]) Wrapped s-CNT Solution Preparation (s-CNT Ink)

Chloroform s-CNT inks were prepared from isolating s-CNTs from CNT soot using a previously established procedure. (G. J. Brady et al., Science Advances, 2016, 2, e1601240.) Briefly, a 1:1 ratio by weight of arc-discharge CNT soot (698695, Sigma-Aldrich) and poly[(9,9-dioctylfluorenyl-2,7-diyl)-alt-co-(6,6′-[2,2′-{bipyridine])] (PFO-BPy) (American Dye Source, Inc., Quebec, Canada; #ADS153-UV) were each dispersed at a concentration of 2 mg mL⁻¹ in ACS grade toluene. This solution was sonicated with a horn tip sonicator (Fisher Scientific, Waltham, Mass.; Sonic Dismembrator 500) and then centrifuged in a swing bucket rotor to remove undispersed material. After centrifugation, the supernatant containing polymer-wrapped s-CNTs was collected and centrifuged for an additional 18-24 h to sediment and pellet the s-CNTs. The collected s-CNT pellet was redispersed in toluene with horn tip sonication and again centrifuged. The centrifugation and sonicating process was repeated a total of three times. The final solution was prepared by horn tip sonication of the s-CNT pellet in chloroform (stabilized with ethanol). s-CNTs prepared via this approach were characterized by a log-normal length distribution with an average length of 580 nm, with diameters varying from 1.3 to 1.8 nm using the methods described in G. J. Brady et al., ACS Nano, 2014, 8, 11614-11621. Concentration of s-CNT ink was determined using optical cross sections from the CNT S₂₂ transition. This solution is referred to as s-CNT.

Surface Pattern Fabrication on Silicon Oxide Substrates

Surface patterns were fabricated using traditional electron-beam lithography techniques. Silicon [100] wafer substrates (Addison Engineering, Inc.) with 90 nm wet thermal silicon oxide were immersed in a 3:1 by volume H₂SO₄:H₂O₂ piranha solution for 1 h at 85° C. After piranha treatment, substrates were rinsed with deionized (DI) water and dried with N₂. For chemical patterns, ma-N 2401 resist (Micro Resist Technologies) was spin coated onto the wafers and patterned using electron-beam lithography techniques. A RIE oxygen plasma for resist descum exposed the silicon oxide. The patterned substrates were submerged in octadecyltrichlorosilane (OTS) (Sigma Aldrich, 104817) at a concentration of 5 mM in toluene for 12 h. Substrates were bath sonicated in toluene for 30 min, rinsed in toluene, and dried with N₂. Resist was stripped by submerging the substrates in anhydrous 1-methyl-2-pyrrolidinone (NMP) (Sigma Aldrich, 328634) for 24 h and drying with N₂. For topographical patterns, PMMA resist (MicroChem Corp.) was spin-coated onto the piranha cleaned silicon substrates and an electron-beam lithography system (Elionix ELS-G100) exposed the PMMA resist with the desired pattern. After PMMA development and oxygen plasma descum, metals were evaporated onto the exposed silicon oxide. PMMA lift off in acetone resulted in metal features on the silicon substrates.

Additional Au chemical functionalization was performed using thiol-based chemistry developed from a previous procedure. (H. Yeon et al., Langmuir, 2017, 33, 4628-4637.) Substrates with Au features were submerged in 1-octadecanethiol (OTh) (01858, Sigma-Aldrich) at a concentration of 1 mM in ethanol for 24 h, rinsed with additional ethanol, and dried with N₂. For both OTS and OTh samples, a control water contact angle measure determined the effectiveness of SAM grafting to substrates. A 7 μL DI water droplet was dispensed using a Dataphysics OCA 15 optical contact angle measuring system on the SAM surface. Once the water droplet was fully formed, the static water contact angle (WCA) of the droplet was immediately measured. Samples were considered fully functionalized if the WCA was greater than 110°. Functionalized silicon oxide substrates were stored under N₂ until s-CNT deposition.

s-CNT Array Fabrication and Characterization

Details of the shear system, and the shear rate control used to deposit s-CNTs, are described elsewhere. (K. R. Jinkins et al., Advanced Electronic Materials, 2019, 5, 1800593.) Chloroform s-CNT ink was sheared across surface patterned silicon substrates at a set shear rate. Additional chloroform solvent was immediately sheared across the same substrate to remove residual s-CNTs. Substrates were boiled in toluene at 110° C. for 1 h and dried with N₂ to remove excess polymer wrapper. Substrates were stored under N₂ until characterization. SEM images were taken with a Zeiss LEO 1550VP SEM. These SEM images were processed using a 2D FFT algorithm to determine s-CNT alignment.

Topographical Pattern Removal

Topographical pattern trenches were removed by etching away the metal between the s-CNT arrays. A thin layer of PMMA was spin coated onto the s-CNTs prior to metal removal to protect the s-CNTs from the metal etchant. Any s-CNTs crossing over the gold mesas were first removed using an oxygen plasma reactive-ion etching procedure. Metal trenches (Au/Cu) were removed by submerging substrates in a standard gold etchant (651818, Sigma-Aldrich) for 5 min and soaking the samples in DI water for 10 min. The iodine-based gold etchant converted Cu to a copper iodine complex that is insoluble in aqueous solution. This process was repeated once to completely convert all Cu. PMMA protective layer and copper iodine complex was removed by boiling acetone at 110° C. for 15 minutes.

Raman spectroscopy measurements of s-CNTs were taken on a Thermo Scientific DXRxi Raman imaging microscope using the mapping function. Raman maps of the s-CNT characteristic bands over 34×34 μm² areas were taken consisting of 1156 pixels where a pixel represents a 1 μm² area.

Chemical Patterns for s-CNT Arrays

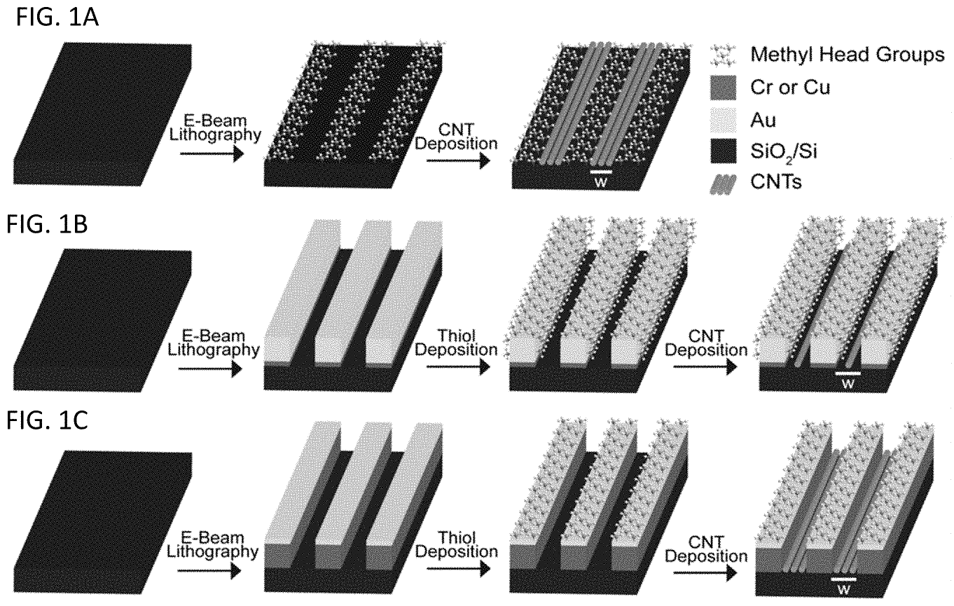

The effectiveness of chemical pattern contrast for selective deposition of s-CNT arrays by shear from an organic ink were first explored. The polymer-wrapped s-CNTs prefer to adsorb on SiO₂ compared to OTS-grafted silicon oxide due to solvent structure effects. To take advantage of s-CNT adsorption preferences to drive selective area deposition, alternating stripes of SiO₂ and OTS were patterned using an electron-beam lithography (EBL) process illustrated in FIG. 1A. A negative tone resist was selected. The crosslinking in the negative tone resist prevented penetration of OTS into the resist during selective functionalization. After OTS functionalization, the negative tone resist was removed resulting in a chemically patterned silicon substrate having alternating stripes of SiO₂ and OTS depicted in FIG. 1A. Individual stripes widths were varied between 250 and 2000 nm where the width of the SiO₂ stripes in the chemical pattern is defined as w (illustrated in FIG. 1A). The OTS stripe width in a chemical pattern is also equal to w at a given SiO₂ stripe width.

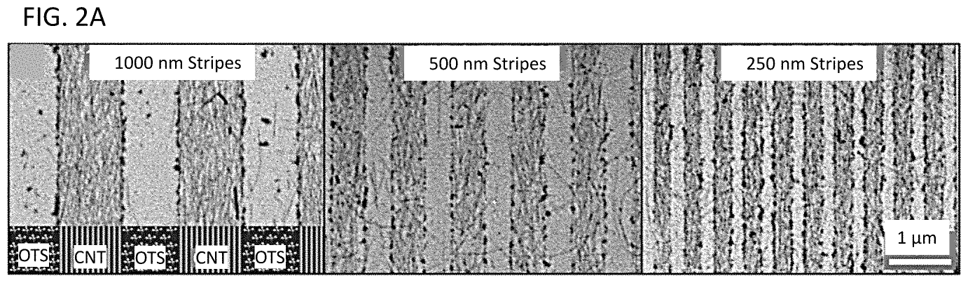

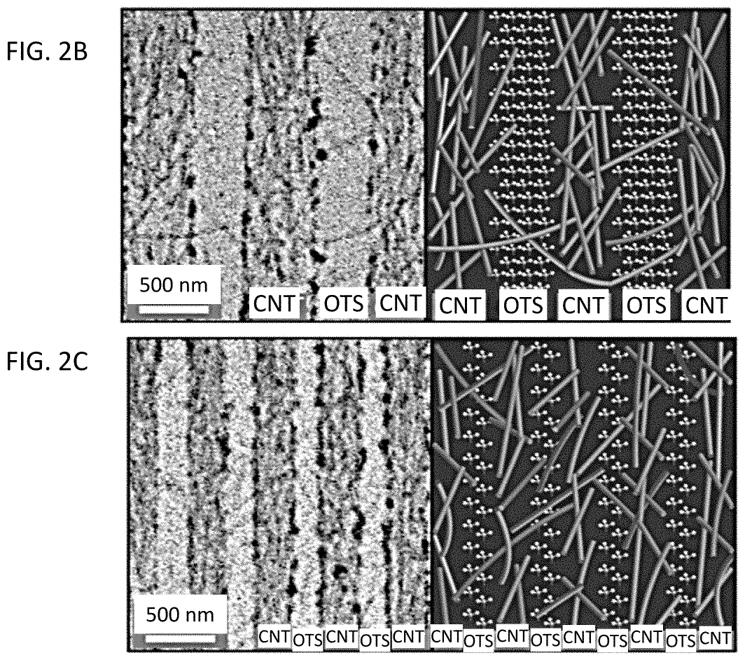

On these chemically patterned substrates, 375 μL of s-CNT ink at a concentration of 240 μg/mL was deposited using a previously established shear deposition method at a high shear rate of 46,000 s⁻¹. (K. R. Jinkins et al., 2019.) FIG. 2A shows the SEM images of s-CNTs deposited on alternating SiO₂ and OTS stripes fabricated using EBL. From these SEM images, the s-CNT density was significantly higher on SiO₂, the favorable s-CNT adsorption surface, compared to OTS, the unfavorable adsorption surface.

FIGS. 2A-2C show s-CNT deposition on the chemically patterned substrates. Alignment of s-CNTs in these arrays was characterized by 2D FFT analysis of SEM images for the deposited s-CNT arrays. 2D FFT analysis has been used for characterizing alignment of various types of fibrous materials including CNT arrays. (E. Brandley et al., Carbon, 2018, 137, 78-87.) The orientation distribution derived from the 2D FFT methodology was fitted with a Gaussian distribution, and the s-CNT alignment degree was quantified by calculating the standard deviation (a) of this curve. As the SiO₂ stripe width w decreased from 2000 nm down to 250 nm, s-CNT alignment stayed constant at a σ of around 18°. Visual inspection of the images shows a number of CNTs that are pinned at the edges of SiO₂ stirpes and extend on to the OTS region as shown in FIGS. 2B-2C. Part of these CNTs were favorably adsorbed to the SiO₂ region but part was unfavorably adsorbed to the OTS. The chemical contrast alone was not strong enough to prevent the deposition of these CNTs, which were often poorly aligned. Increasing the spacing between the SiO₂ stripes to 5000 nm did not significantly reduce CNT pinning at the edges of the pattern or improve the resulting a, evidencing that the deposition of these CNTs was not driven by bridging from one SiO₂ region to the next. Additionally, increasing the spacing between SiO₂ stripes was not practical when fabricating dense sets of devices on a single substrate, which required us to focus further efforts on reducing this pinning of CNTs across stripes.

Topographical Patterns for s-CNT Arrays

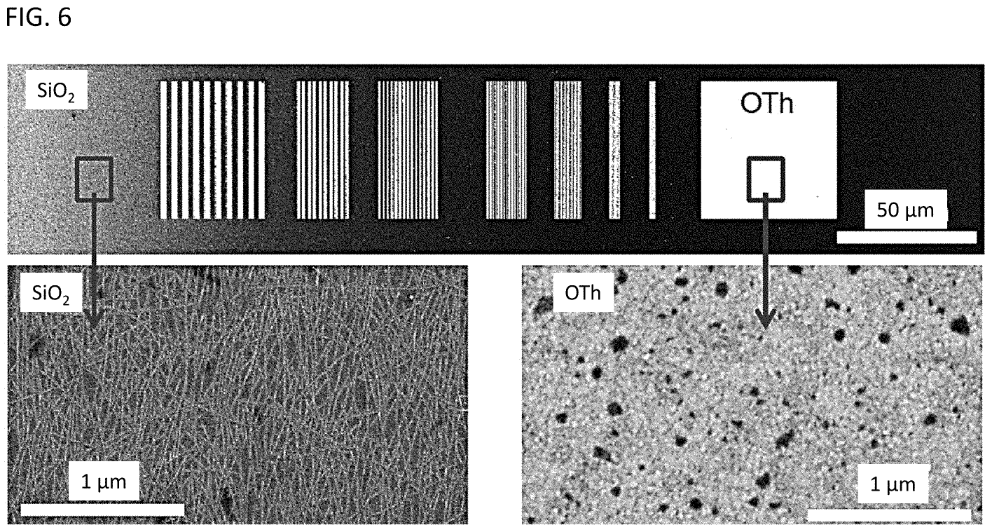

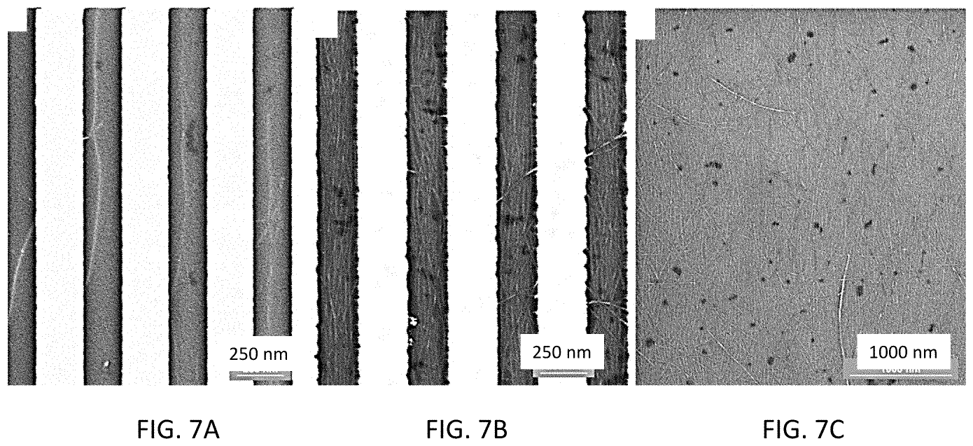

The addition of a physical barrier to the chemical patterns on the silicon substrate was used to significantly improve CNT alignment on SiO₂ stripes as well as limit pinning across OTS stripes. The design and fabrication of the topographical surface patterns with integrated chemical patterns are illustrated in FIGS. 1B and 1C. The trench floors were bare SiO₂ acting as the favorable CNT deposition surface while the mesas acted as the unfavorable deposition surface. The mesas needed to be fabricated from a material that could be selectively functionalized without modifying SiO₂ on the trench floor. For fabrication simplicity, gold was picked for the mesas as it could be selectively functionalized with OTh, a thiol terminated SAM. To improve adhesion of gold to SiO₂ substrate, chromium or copper was used as an adhesion layer. The height of the Au/Cr stack was 25 nm, a value 10-20 times greater than the diameter of the s-CNTs. Functionalization of Au with OTh prevented s-CNTs from depositing onto the Au surface (FIG. 6). Trenches of 22.5 nm Au on 2.5 nm Cr, led to functionalization of Au with OTh on both the mesas and the side walls (FIG. 1B). However, the overall density of the s-CNTs deposited in these patterns was an order of magnitude lower than on bulk SiO₂ substrates, possibly due to the disruption of solvent structure along the Au sidewalls (FIGS. 7A-7C). To reduce the thickness of Au, the procedure outlined in FIG. 1C, with a thin 2.5 nm Au top layer and 22.5 nm Cr in the 25 nm Au/Cr metal stripe stack, was implemented to prevent OTh functionalization of the trench sidewalls.

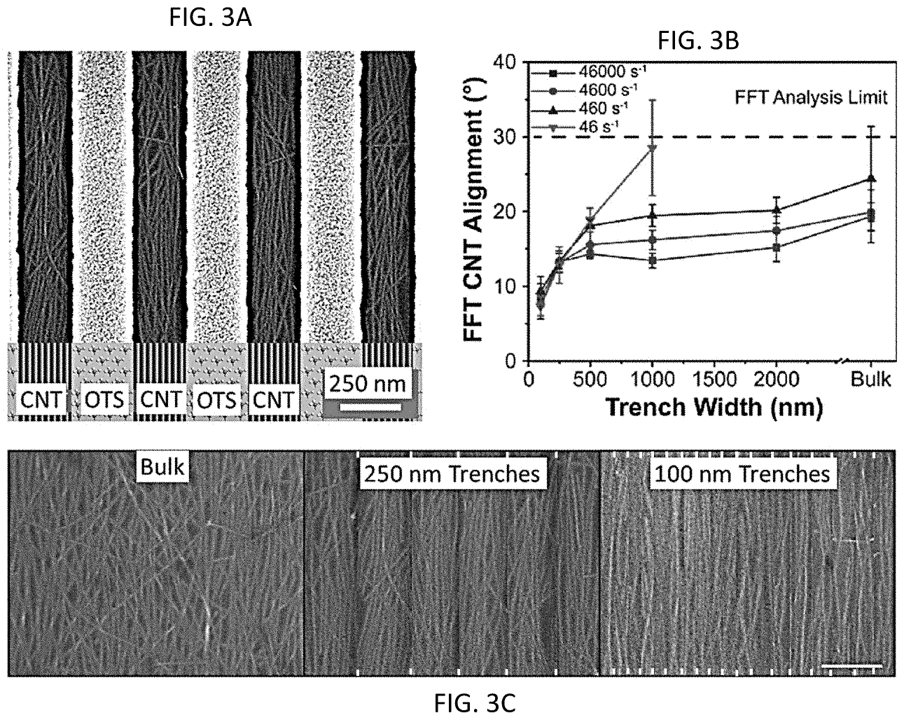

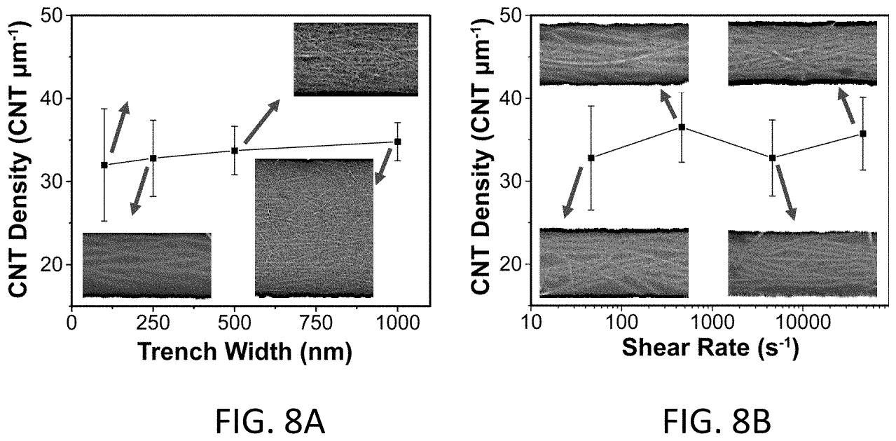

These modified patterns were effective in increasing the density of the deposited s-CNTs from approximately 10-15 to over 30 CNTs μm⁻¹ in the trenches while minimizing their deposition on the mesas (FIG. 3A). By averaging the number of s-CNTs in five trenches, their density as a function of both w and deposition shear rate was quantified (FIGS. 8A-8B). At a constant deposition shear rate of 4,600 s⁻¹, the s-CNT density was relatively constant at 32-36 CNTs μm⁻¹ even when w was varied from 100-1000 nm. Inherently larger error bars were observed for narrower trenches due to the lower number of CNTs. For the shear rates ranging from 46 to 46,000 s⁻¹, the s-CNT density again remained constant around 32-35 CNTs μm⁻¹, when w was fixed at 250 nm.

The 2D FFT metrology method was applied to quantify the s-CNT alignment in these topographical patterns as discussed earlier. FIG. 3B shows σ from the aligned s-CNT arrays as a function of both shear rate and trench width. The bulk data points are defined as s-CNT deposition on unpatterned, planar SiO₂. For the FFT analysis, a standard deviation greater than 30°, corresponding to non-preferentially oriented s-CNT films, was defined as the maximum limit. Visual inspection of SEM images of both a low shear rate (46 s⁻¹) in the 2000 nm wide trenches as well as bulk samples confirms the random distribution with a σ>30°. At a constant w, CNT alignment improved with increasing shear rate. At a constant shear rate, s-CNT alignment also improved with decreasing w down to 100 nm. The best alignment with a σ of 7.6±0.3° was observed at a shear rate of 4,600 s⁻¹ in 100 nm trenches. FIG. 3C shows SEM images of CNT arrays in multiple trenches stitched together (denoted by marks along the bottom of the image) highlighting the dramatically improved CNT alignment in narrower trenches compared to bulk deposition for a given shear rate.

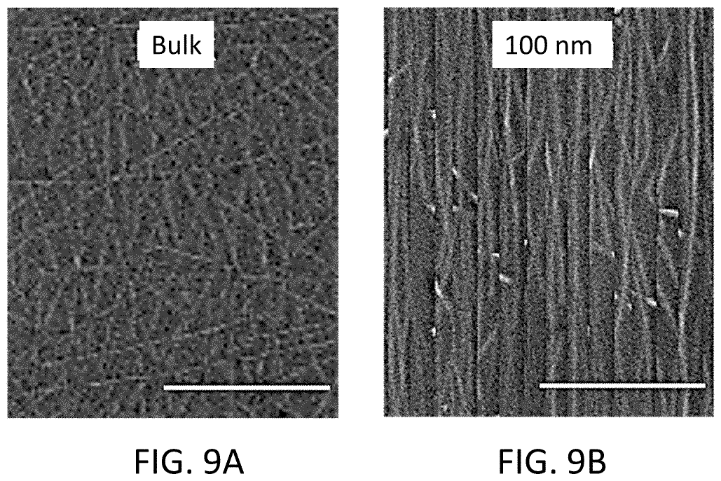

The studies presented here uncover important guidelines to achieving exceptionally aligned s-CNT arrays while selectively depositing them in desired regions of the substrate. These studies show that increasing the shear rate during s-CNT deposition does not indefinitely increase their alignment in the trenches. When the patterns were wider than the length of the s-CNT (>500 nm), increase in shear rate led to quasi aligned CNTs, with a σ of 14°. For example, while increasing shear rate from 46 s⁻¹ to 4600 s⁻¹ dramatically improved the alignment from 28.5±6.3° to 16.2±1.3° in 1-micron wide trenches, a further increase to 46,000 s⁻¹ resulted in a marginal improvement to a σ of 13.3±1.0°. When the pattern width was reduced to less than the length of the individual CNTs 500 nm), confinement effects dominated over shear rate, leading to a dramatic enhancement in the alignment degree. For example, using a low shear rate of 46 s⁻¹ with a 100 nm wide trench achieved an alignment degree of 7.6±1.3°. This alignment degree is remarkable in comparison to the alignment degree of 19.3±3.5° at the high shear rate (46,000 s⁻¹) on planar SiO₂ (FIGS. 9A-9B).

Chemical patterns of alternating OTS and SiO₂ stripes resulted in a constant s-CNT alignment degree ˜18° regardless of the stripe width, whereas the addition of a topographical pattern consisting of 25 nm tall metal stripes improved s-CNT alignment from 19.3±3.5° at a deposition shear rate of 46,000 s⁻¹ on bulk SiO₂ to 8.5±2.8° in 100 nm wide trenches. Hence, the alignment can be improved by decreasing the trench width, provided both the trench width is sufficiently narrow (below 500 nm) and the trench height is sufficiently high to prevent s-CNTs from depositing on multiple SiO₂ stripes. Based on experimental results, trench heights over 25 nm did not further improve s-CNT alignment degree. s-CNT alignment on these patterned substrates was uniform across the 2×3 cm² SiO₂/Si substrates, demonstrating the inherent scalability of this process. Larger area deposition can be achieved by scaling up the shear deposition system.

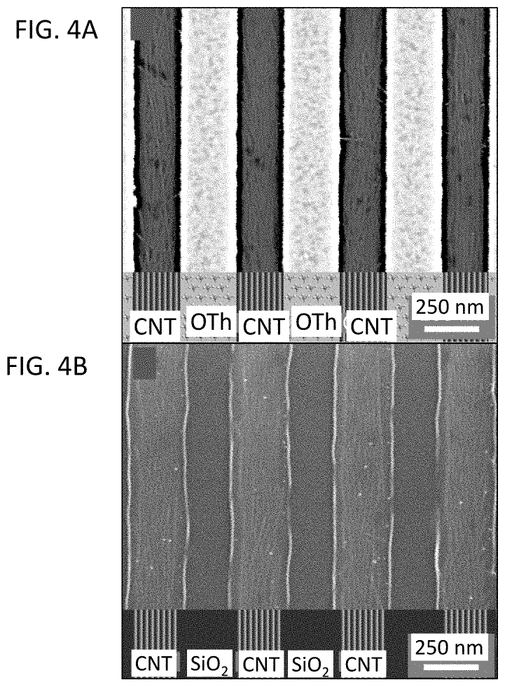

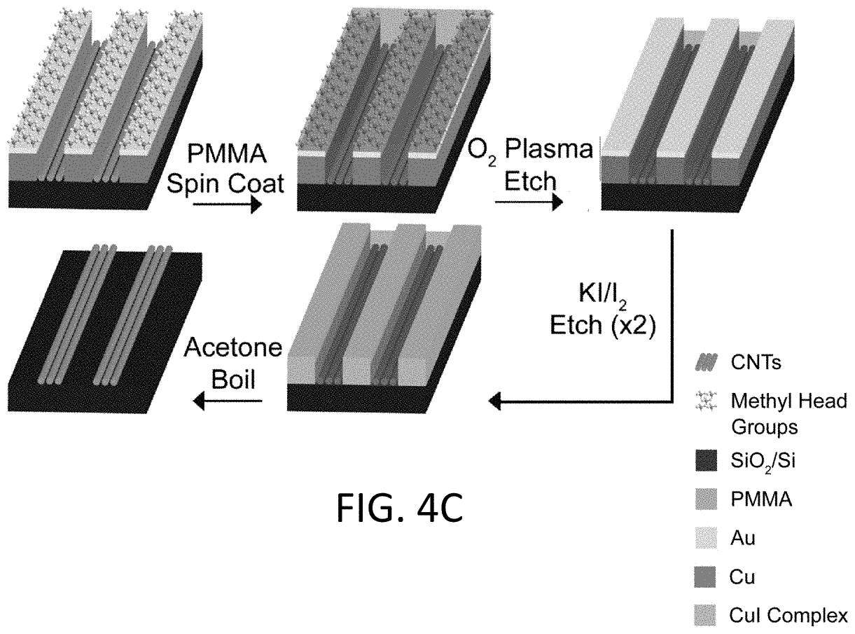

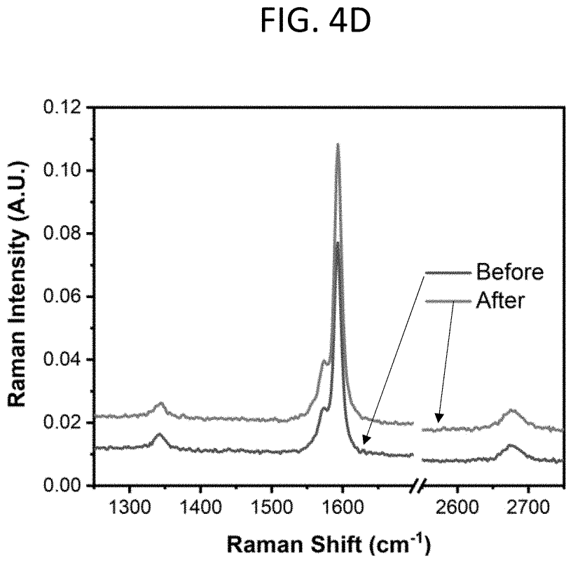

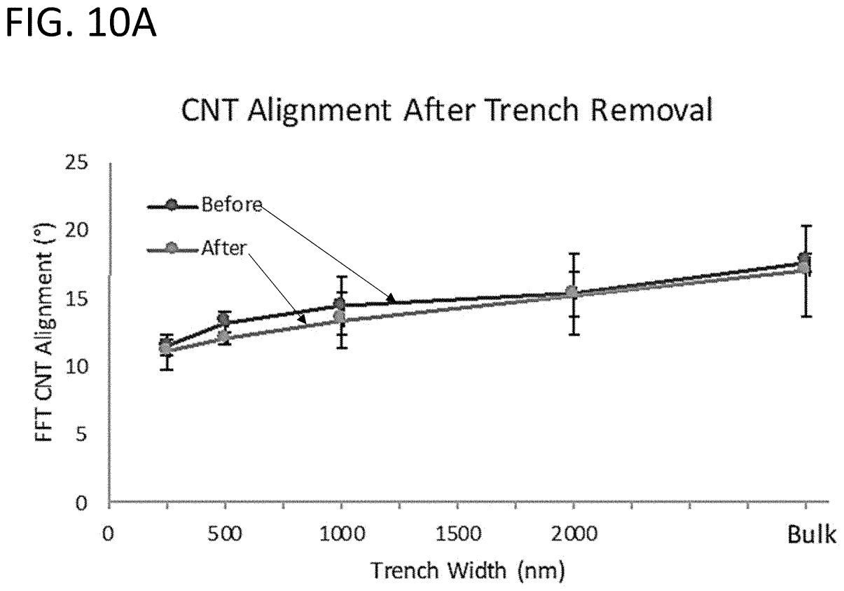

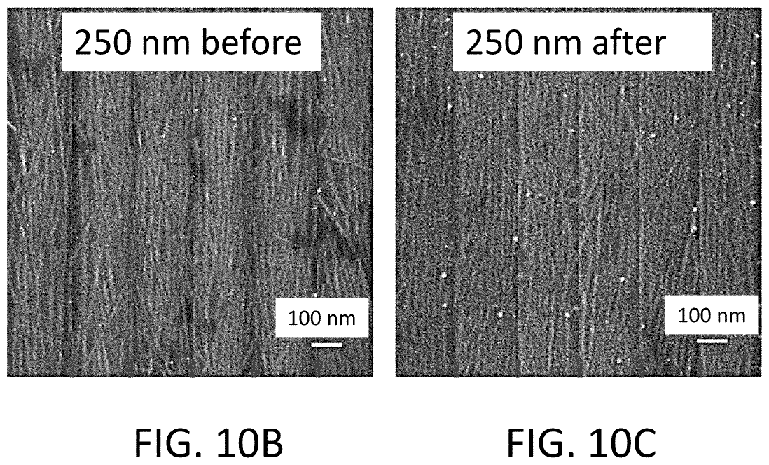

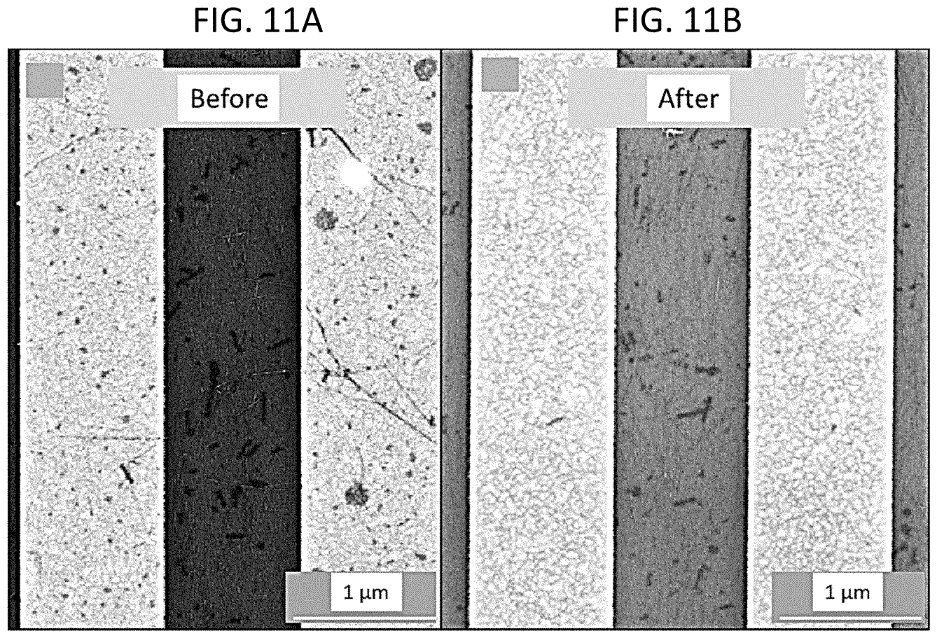

Another desirable criterion for this pattern design to be compatible with device fabrication is to completely remove any residual metals post-CNT deposition. For these experiments, Cr, an adhesion layer for Au, was substituted with Cu in the fabrication scheme shown in FIG. 1C because standard Cr etchants attack a PMMA protective layer on the CNTs, unlike Cu etchants. SEM images of s-CNT arrays before (FIG. 4A) and after (FIG. 4B) trench removal confirm that the alignment of the s-CNT was preserved (FIGS. 10C-10C and FIGS. 11A-11B), making this removal process compatible with FET device fabrication. Another consequence of the trench removal process is that any crossing tubes that might bridge between the SiO₂ stripes are also removed.

To ensure the electronic properties of the s-CNTs are preserved, the Raman spectrum of s-CNTs was examined before and after exposure to Au/Cu trench removal treatments. Analysis of the ratio of D to G band intensities (I_{D}/I_{G}) is commonly used to examine electronic defects in CNTs. (M. J. Shea et al., APL Materials, 2018, 6, 056104.) Spin coated s-CNTs on 90 nm SiO₂/Si substrates were used for these tests to increase the signal of G, D, 2D, and Si Raman peaks. These samples were subjected to the same trench removal process as used in FIGS. 4A-4D. Raman spectra of s-CNTs were taken over a 34 μm² area and averaged into a single spectrum. FIG. 4D shows the averaged Raman spectra of the s-CNTs before and after trench removal. Before processing, the I_{D}/I_{G} of the s-CNTs was 0.20±0.02. After the trench removal process, s-CNTs had an I_{D}/I_{G} of 0.15±0.02. These data show the trench removal process did not adversely affect the electronic properties of the CNTs. The slight improvement in the I_{D}/I_{G} was likely due to increased removal of residual polymer-wrapper due to the gold etchant. Adsorbates on CNTs will also suppress G band intensity, hence lowering I_{D}/I_{G}. These results confirm that the electronic quality of the starting s-CNTs was preserved throughout the processing steps, making this removal process compatible with FET device fabrication.

Pre-alignment of s-CNTs via shear played a major role when the trench width was >500 nm wide or larger than the length of the CNTs. However, when the trench width decreased below 500 nm, the confinement effect dominates over shear. At a trench width of 100 nm, exceptional degree of alignment (with a G of 7.6±0.3° at a shear rate of 4,600 s⁻¹), was achieved while maintaining a density greater than 30 CNTs μm⁻¹. The rotational diffusion coefficient quickly decreased as the s-CNT length increased thereby aiding in shear alignment. Hence, the pre-alignment by shear forces and confinement effect in trenches can both be enhanced by increasing the average s-CNT length.

Characterization of CNT Alignment using 2D FFT Method

The s-CNT alignment was characterized by performing a 2D FFT analysis of SEM images for the deposited s-CNT arrays.

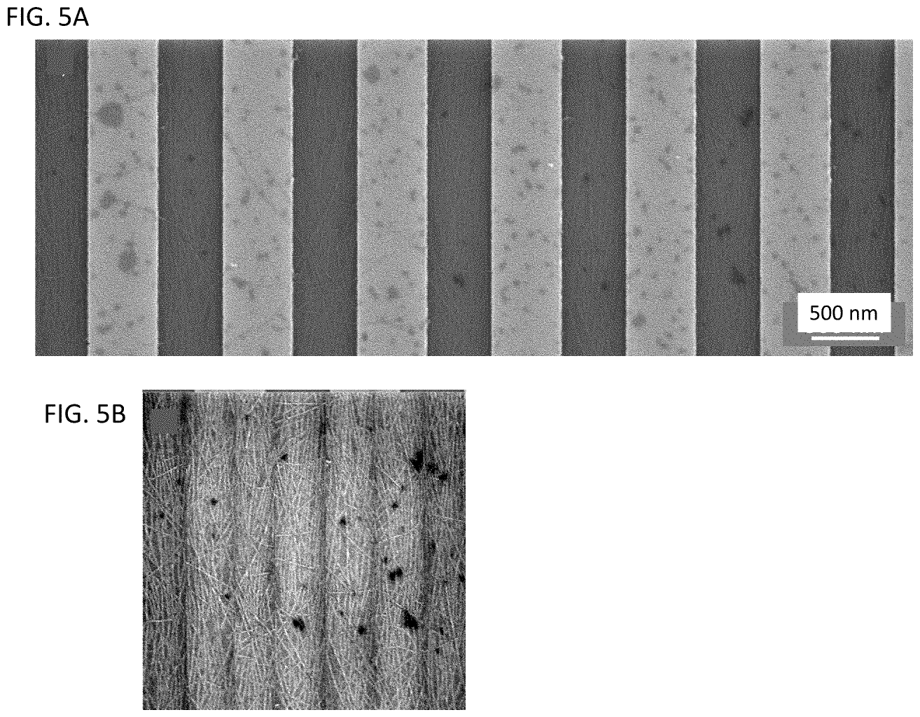

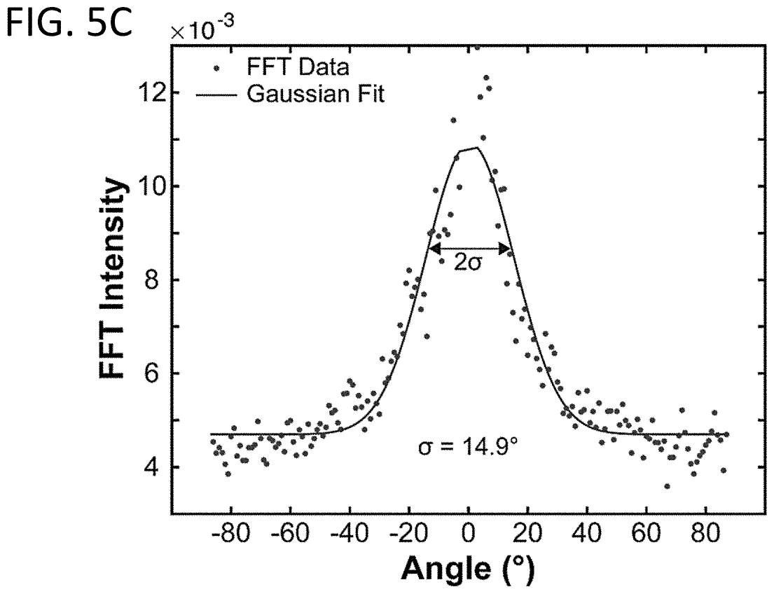

The alignment of the carbon nanotube arrays was characterized by performing 2D FFT analysis of SEM images of the deposited arrays. including CNT arrays. The analysis procedure was similar to that described by Brandley et al. and adapted to account for the presence of topographical trenches. (Brandley, E. et al., Carbon. 2018, 137, 78-87.) The following steps were followed for the 2D FFT analysis: First, an SEM image of the CNT array was prepared for analysis (FIG. 5A). The mesas between trenches were removed from the image, and the images of the trenches were “stitched” together into a single image (FIG. 5B). Removing the mesas reduced noise and reduced the amplitude of a large bright peak at low frequency in the FFT image that could overwhelm the desired signal from the CNT array.

Second, the 2D FFT of the prepared image was calculated using the fft2 function in Matlab™. The FFT was shifted to the center of the image using the fftshift function in Matlab™ for a more convenient representation. The FFT showed a pattern of bright lobes oriented perpendicular to the main direction of orientation of the CNT array.

Finally, the orientation distribution was obtained by integrating the intensity of the shifted FFT from a distance fₘᵢₙ to a distance fₘₐₓ from the center of the image, at angles varying from −90° and 90°. In practice, the image was rotated using the function imrotate in Matlab™ at each angle of interest using a nearest-neighbor interpolation scheme. The intensity was averaged over the horizontal axis from fₘᵢₙ to fₘₐₓ. Bright peaks at spatial frequencies below fₘᵢₙ=N/(2tₘᵢₙ), where N represents the number of pixels and tₘᵢₙ is the minimum pixel threshold, correspond to large scale fluctuations associated, for example, with uneven illumination or stitching of multiple trench images. Spatial frequencies above fₘₐₓ=N/(2tₘₐₓ), where tₘₐₓ is the maximum pixel threshold, correspond to speckle noise. It was verified that small changes to the values of fₘᵢₙ and fₘₐₓ affect the measured σ of the fiber distribution by less than 1°. In general, it was found that tₘᵢₙ=10 pixels and tₘᵢₙ=2 pixels worked well for most of the images. Finally, the orientation distribution was fitted with a Gaussian distribution to obtain σ (FIG. 5C).

The 2D FFT method is limited to orientation distributions that are fully contained within the range −90° to 90°. For a normal distribution, this means that results will not be accurate for arrays with a standard deviation greater than approximately 30°. At greater standard deviations, only a fraction of the orientation distribution is known. Because the baseline value (the offset value that would be returned by the 2D FFT algorithm for a zero probability at a given angle—this value is never zero in practice and is affected by noise in the images) is unknown, it is impossible to obtain a curve fitting of the orientation distribution with accuracy. In these measurements, only two data points (at a low shear rate of 46 s⁻¹ for bulk and 2000 nm wide trenches) had an orientation distribution with a standard deviation greater than 30°. Visual inspection of the SEM images for these two cases confirms that the CNT array shows virtually no preferential direction of alignment.

The 2D FFT method was validated by comparing its results with orientation distributions obtained by manual counting of individual nanotubes for a selection of images. In all the tested images, the 2D FFT method tended to overestimate the standard deviation of the orientation distribution with an error of no more than 5°.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” can mean only one or can mean “one or more.” Embodiments of the inventions consistent with either construction are convered.

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A method of forming a film of aligned carbon nanotubes in a trench, the trench defined by:
a trench floor, a first sidewall mesa that provides a first trench sidewall, a second sidewall mesa that provides a second trench sidewall disposed opposite the first trench sidewall, and organic chemical groups functionalizing at least a portion of the first sidewall mesa and at least a portion of the second sidewall mesa,
the method comprising:
flowing a suspension of carbon nanotubes through the trench, wherein carbon nanotubes in the flowing suspension are deposited onto the trench floor to form a film of aligned carbon nanotubes.

2. The method of claim 1, wherein only a top surface of the first sidewall mesa and a top surface of the second sidewall mesa is functionalized by the organic chemical groups.

3. The method of claim 1, wherein at least a portion of the first trench sidewall adjacent to the trench floor is not functionalized by the organic chemical groups and at least a portion of the second trench sidewall adjacent to the trench floor is not functionalized by the organic chemical groups.

4. The method of claim 3, wherein the portions of the first and second trench sidewalls that are not functionalized by the organic chemical groups comprise a first material and the portions of the first and second trench sidewalls that are functionalized by the organic chemical groups comprise a second material.

5. The method of claim 4, wherein the first material and the second material are two different metals.

6. The method of claim 5, wherein the first material is chromium or copper and the second material is gold.

7. The method of claim 6, wherein the organic chemical groups comprise alkyl groups and form self-assembled monolayers on the first and second sidewall mesas.

8. The method of claim 1, wherein the trench floor is hydrophilic and the organic chemical groups are hydrophobic.

9. The method of claim 8, wherein the hydrophilic trench floor comprises silicon dioxide.

10. The method of claim 9, wherein the carbon nanotubes are single-walled carbon nanotubes coated with an organic material.

11. The method of claim 10, wherein the organic chemical groups comprise alkyl groups and form a self-assembled monolayer on the first and second sidewall mesas.

12. The method of claim 1, wherein the first sidewall mesa and the second sidewall mesa are metal mesas.

13. The method of claim 12, wherein the first sidewall mesa and the second sidewall mesa both comprise a layer of a first metal adjacent to the trench floor and a layer of a second metal disposed over the layer of the first metal.

14. The method of claim 13, wherein the first metal is chromium or copper and the second metal is gold.

15. The method of claim 14, wherein the trench floor comprises silicon dioxide.

16. The method of claim 15, wherein the carbon nanotubes are single-walled carbon nanotubes coated with an organic material.

17. The method of claim 1, wherein the trench has a width that is smaller than the average length of the carbon nanotubes in the suspension.

18. The method of claim 17, wherein the carbon nanotubes have an average length in the range from 100 nm to 1000 nm.

19. The method of claim 1, wherein the carbon nanotubes have an average diameter in the range from 1 nm to 2 nm.

20. The method of claim 1, further comprising removing the first and second sidewall mesas.
